(19) United States
(12) Patent Application Publication
(10) Pub. No.: US 2017/0271410 A1
(43) Pub. Date: Sep. 21, 2017

(54) NONVOLATILE MEMORY CROSSBAR ARRAY

(71) Applicant: Hewlett Packard Enterprise Development LP, Houston, TX (US)

(72) Inventors: Minxian Max Zhang, Mountain View, CA (US); Kathryn Samuels, Palo Alto, CA (US); Jianhua Joshua Yang, Palo Alto, CA (US); R. Stanley Williams, Portola Valley, CA (US); Zhiyong Li, Foster City, CA (US)

(21) Appl. No.: 15/500,049

(22) PCT Filed: Feb. 11, 2015
(86) PCT No.: PCT/US2015/015393

§ 371 Date: Jan. 28, 2017

(51) Int. Cl. H01L 27/24

(52) U.S. Cl. CPC H01L 27/2418; H01L 27/2463

(57) ABSTRACT

Provided in one example is a nonvolatile memory crossbar array. The array includes a number of junctions formed by a number of row lines intersecting a number of column lines; and a resistive memory element in series with a selector at each of the junctions coupling between one of the row lines and one of the column lines. The selector may be a volatile switch including: a bottom electrode; an oxide layer disposed over the bottom electrode, the oxide layer including Cu₂O; and a top electrode disposed over the oxide layer.

### BACKGROUND

Resistive memory elements often referred to as memristors are devices that may be programmed to different resistive states by applying electrical voltage or currents to the memristors. After programming the state of the memristors, the memristors may be read. The state of the memristors remains stable over a specified time period long enough to regard the device as nonvolatile. A number of memristors may be included within a crossbar array in which a number of column lines intersect with a number of row lines at junctions, and the memristors are coupled to the column lines and row lines at the junctions.

### BRIEF DESCRIPTION OF THE DRAWINGS

The drawings are provided to illustrate various examples of the subject matter described herein in this disclosure (hereinafter “herein” for short, unless explicitly stated otherwise) related to a nonvolatile memory crossbar array and are not intended to limit the scope of the subject matter. The drawings are not necessarily to scale.

FIG. 1 is a schematic diagram showing one example of a nonvolatile memory crossbar array described herein.

FIG. 2 is a schematic diagram showing the circuit diagram of one example of a nonvolatile memory array described herein.

FIG. 3 is a schematic diagram showing one example of a selector described herein,

FIG. 4 is a schematic diagram showing one example of a system described herein.

FIG. 5 is a flowchart showing the processes involved in one example of a method of manufacturing described herein.

FIGS. 6A-6B show I-V behaviors of a selector described herein for one cycle (6A) and 100 cycles (6B).

### DETAILED DESCRIPTION

Resistive random-access memories are devices that may be used as components in a wide range of electronic circuits, such as memory devices, switches, radio frequency circuits, and logic circuits and systems. When used as a basis for a memory device, the resistive random-access memory may be used to store bits of information, e.g., 1 or 0. The resistance of a resistive random-access memory may be changed by applying an electrical stimulus, such as a voltage or a current, through the resistive random-access memory. Generally, at least one channel may be formed that is capable of being switched between two states—one in which the channel forms an electrically conductive path (“ON”) and one in which the channel forms a less conductive path (“OFF”).

Several memory devices may be incorporated together into a crossbar array of memory devices. However, using resistive random-access memories in a crossbar array may lead to read or write error due to sneak path currents passing through the memory devices that are not targeted, such as device(s) on the same row or column as a targeted device. Error may arise when the total operating current through the crossbar array from an applied voltage cannot operate the selected resistive random-access memory. This may be due to current sneaking from the selected memristor through to untargeted neighboring device(s). Using a transistor coupled in series with each memristor has been proposed to isolate each device and overcome the sneak path current. However, using a transistor with each memristor in a crossbar array may limit array density and increase cost.

In view of the aforementioned challenges related to sneak path currents, the Inventors have recognized and appreciated the advantages of a crossbar array having certain types of selectors. Following below are more detailed descriptions of various examples related to a memory crossbar array, particularly a nonvolatile memory crossbar array having selectors including CuOₓ. The various examples described herein may be implemented in any of numerous ways.

Provided in one aspect of the examples is a nonvolatile memory crossbar array, including: a number of junctions formed by a number of row lines intersecting a number of column lines: and a resistive memory element in series with a selector at each of the junctions coupling between one of the row lines and one of the column lines, the selector being a volatile switch including: a bottom electrode; an oxide layer disposed over the bottom electrode, the oxide layer including Cu₂O; and a top electrode disposed over the oxide layer.

Provided in another aspect of the examples is a system, including: a processor; and a nonvolatile memory crossbar array coupled to the processor, the memristor crossbar array including: a number of junctions formed by a number of row lines intersecting a number of column lines; a resistive memory element in series with a selector at each of the junctions coupling between one of the row lines and one of the column lines, the selector being a volatile switch including: a bottom electrode; an oxide layer disposed over the bottom electrode, the oxide layer including Cu₂O; and a top electrode disposed over the oxide layer; and a current collection line to collect all currents output from the resistive memory element and the selector at the junctions through their respective column lines.

Provided in another aspect of the examples is a method of manufacturing, including: making a plurality of volatile selectors, the making including: forming a bottom electrode over a portion of substrate including silicon; forming an oxide layer over a portion of the bottom electrode, the oxide layer including Cu₂O; and forming over a portion of the oxide layer a top electrode; and assembling a resistive memory element with one of the volatile selectors to couple one of a number of junctions formed by a number of row lines intersecting a number of column lines of a nonvolatile memory crossbar array.

Resistive Random-Access Memory

The term “memristance” herein may refer to the phenomenon that when charge flows in one direction through a circuit, the resistance of that component of the circuit will increase; and when charge flows in the opposite direction in the circuit, the resistance will decrease. When the flow of charge is stopped by turning off the applied voltage, the component will “remember” the last resistance that it had, and when the flow of charge starts again the resistance of the circuit will be what it was when it was last active. In one example, a resistance memory element is a resistor device whose resistance may be changed.

The term “resistive memory element” herein may refer to a programmable nonvolatile memory where the switching mechanism involves ionic motion, including valance change memory, electrochemical metallization memory, and others. Resistive memory elements may be employed in a variety of applications, including nonvolatile solid state memory, programmable logic, signal processing, control systems, pattern recognition, and other applications. One example of a resistive memory element is a resistive random-access memory (“ReRAM”). A ReRAM may work by changing the electrical resistance across a dielectric solid-state material that may include a memristor. Examples of ReRAM include a memristor, a phase-change memory, a conductive-bridging RAM, and a spin-transfer torque RAM. Merely to facilitate the explanation and for the sake of convenience, a memristor is employed in several examples herein to describe a ReRAM; however, it is appreciated that the description may be applicable to other types of ReRAM.

Memristive devices, such as ReRAM, such as memristors, are devices that may be used as a component in a wide range of electronic circuits, such as memories, switches, and logic circuits and systems. The conductance channels in the ReRAMs may be formed in each ReRAM, and each ReRAM may be individually addressed as bits. The ReRAM may be built at the micro- or nano-scale. When used as a basis for memories, the ReRAM may be employed to store a bit of information, 1 or 0. When used as a logic circuit, the ReRAM may be employed to represent bits in a field programmable gate array, as a basis for a wired-logic programmable logic array. The ReRAM may be fabricated through any reasonably suitable fabrication process, such as, for example, chemical vapor deposition, sputtering, etching, lithography, or other methods of forming memristors.

In a memory structure, a nonvolatile memory crossbar array of ReRAMs (e.g., memristors), such as a memristive crossbar array (“MCA”) for short herein, may be employed. In one example, a crossbar array is an array of switches that connect each wire in one set of parallel wires to every member of a second set of parallel wires that intersects the first set—e.g., row lines intersecting column lines. For example, when employed as a basis for memories, a ReRAM may be employed to store bits of information, in the form of 1 or 0, corresponding to whether the memristor is in its high or low resistance state (or vice versa). When employed as a logic circuit, a ReRAM may be employed as configuration bits and switch in a logic circuit similar to a Field Programmable Gate Array, or may be the basis for a wired-logic Programmable Logic Array. It is also possible to employ ReRAMs capable of multistate or analog behavior for these and other applications.

When employed as a switch, the ReRAM, of which memristor is one example, may either be in a low resistance (closed) state or high resistance (open) state in a cross-point memory. The resistance of a ReRAM may be changed by applying an electrical stimulus, such as a voltage or a current, through the ReRAM. Generally, at least one channel may be formed that is capable of being switched between two states—one in which the channel forms an electrically conductive path (“ON”) and one in which the channel forms a less conductive path (“OFF”). In some other cases, conductive paths represent “OFF” and less conductive paths represent “ON.”

Nonvolatile Memory Crossbar Array

Nonvolatile memory crossbar arrays (of ReRAM, of which memristor is one example) may be employed in a variety of applications, including nonvolatile solid state memory, programmable logic, signal processing, control systems, pattern recognition, and other applications.

The nonvolatile memory crossbar array (or “array” for short) described herein may include a number of suitable components. The term “a number of” or similar language herein may refer to any positive number from 1 to infinity. The array may include a number of row lines and a number of column lines intersecting the row lines to form a number of junctions.

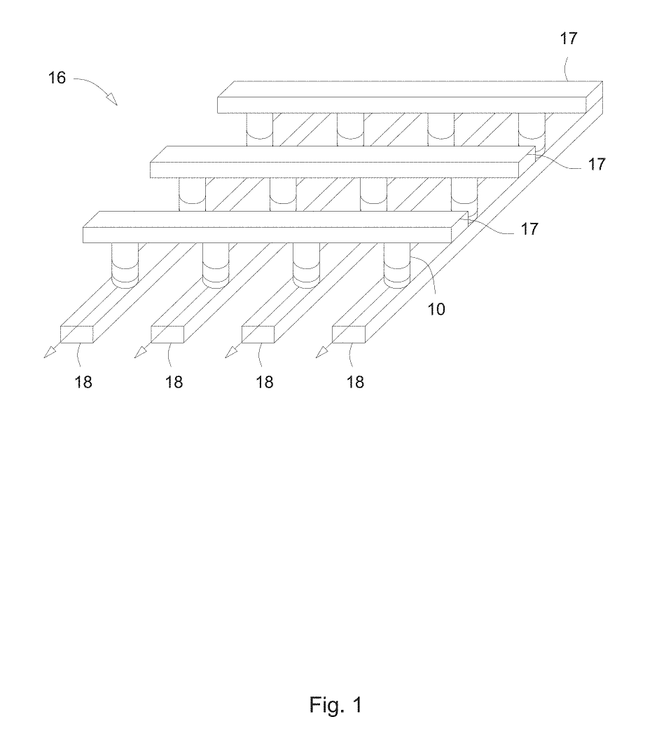

FIG. 1 is a schematic of a nonvolatile memory crossbar array (16) of resistive memory devices (10). As shown in this figure, each resistive memory device (10) is sandwiched between two conductive layers (17) and (18), which are conductive interconnects that may be a metal-containing material, including a pure metal, a metal alloy, a metal compound, and the like. As will be described further below, each resistive memory device (10) may include a resistive memory element and a selector. In one example, the resistive memory element is a ReRAM, such as a memristor. In one example, the resistive memory element and the selector may be connected in series. The term “in series” means that the components are electrically connected along a single path so that the same current flows through all of the components. While the components may be in series, they may or may not be in direct contact with one another, and the order of the components may vary.

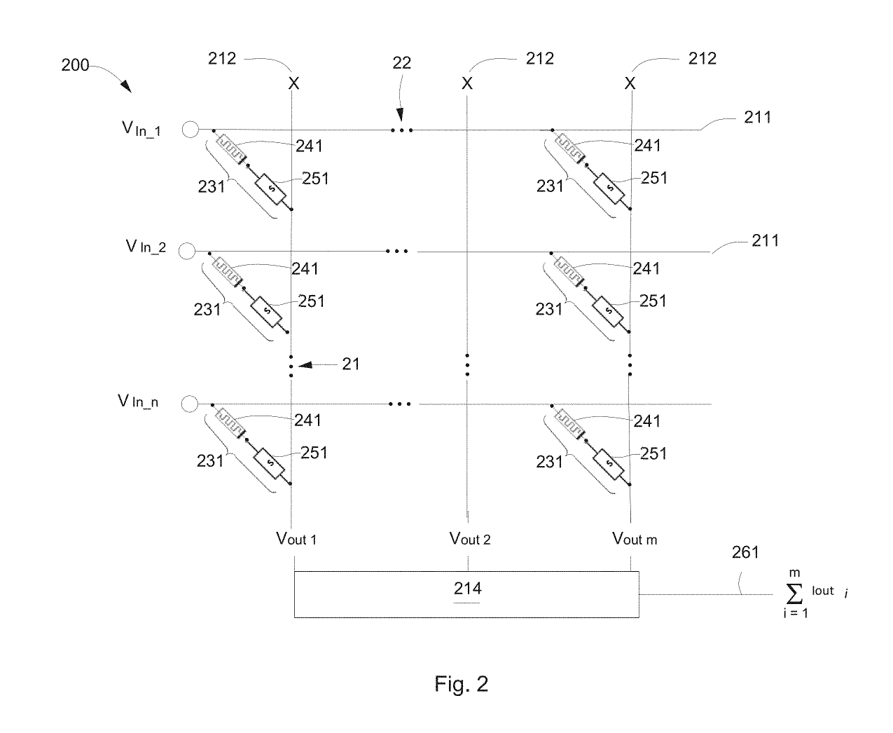

FIG. 2 is a schematic circuit diagram of one example of a nonvolatile memory array, such as the array (16) as shown in FIG. 1. It is noted that although the nonvolatile memory array (200) of FIG. 2 is depicted as having a circuit layout as depicted, any number of circuit layouts may be used to achieve the functions the systems and methods described herein. The nonvolatile memory array as depicted in FIG. 2 includes the row lines (211), the column lines (212), and resistive memory devices (231) such as those corresponding features shown in FIG. 1. Any number of row lines and column lines may be included within the nonvolatile memory array as indicated by the ellipses (21, 22).

The row lines (211) and the column lines (212) may intersect to form junctions (or “cross points”). At each junction, the array may include a resistive memory device (231), such as the device (10) shown in FIG. 1. It is noted while FIG. 2 shows that each junction has a resistive memory device (10), this need not be the case and only some of the junctions may have resistive memory devices. Each resistive memory device (231) may include a resistive memory element (241) and a selector (251). As described above, the resistive memory element (241) and selector (251) may be connected in series. The resistive memory element (241) may be ReRAM, such as any of those described herein. The selector (251) may be any of those described herein.

Depending on the application, the nonvolatile memory crossbar array (200) may include a number of input voltages indicated as Vin_1, Vin_2, . . . , Vin_n. The input values may be program signals used to change the resistance values at the resistive memory element of each resistive memory device at each junction in the crossbar array to create a representation (e.g., a mapping) of a mathematic matrix in which each value at each junction represents a value within the matrix. This change in resistance among the resistive memristive elements of the resistive memory device may be an analog change from a low-to-high value or a high-to-low value. In one example, the resistive memory elements are “memory resistors” in that they “remember” the last resistance that they had—e.g., ReRAM.

The array described herein may also include a current collection line (261) to collect currents from the column lines (212). In one example, the current collection line collects currents from resistive memory devices (231_{—} (including the resistive memory elements (241) and the selectors (251)) of the different junctions through their respective column lines and output a result current. As shown in FIG. 2, a conversion circuit (214) may be placed before the collection line (261), particularly when current amplifiers are used (not shown). It is noted that a conversion circuit need not be used in all instances. While voltages and currents are described herein as being collected at the ends of column lines and further collected using the collection line, any circuit topology or design may be employed to obtain a desired output such as a voltage value, a current value or other circuit parameter.

The resistive memory element, such as (241) as shown in FIG. 2, herein may be any type of ReRAM, such as a memristor. The resistive memory elements (241) at the different junctions may be the same or different from each other. In one example, the resistive memory elements at the different junctions are different from each other. The difference may be with respect to the materials, design, properties, etc. of the elements. In one example, the different resistive memory elements of the different sets have different preset conductance values from one another.

A number of selectors may be included within a nonvolatile memory crossbar array. The selectors may be placed in series with each resistive element at each junction as depicted in FIG. 2. The selectors at the different junctions may be the same or different from each other. Although one selector is depicted in FIG. 2 to provide for clarity within the figure, any number of selectors may be placed in series with each of the resistive memory element. A selector, such as (251) as shown in FIG. 2, may be employed in an electronic device to aid in controlling the electrical properties of the device. One example of such control is reducing sneak path currents.

A selector may refer to a circuit element that screens the resistive memory element (e.g., ReRAMs) from sneak current paths to ensure that only the selected bits represented by the ReRAMs are read or programmed. A selector may be a switch. In one example, the selector is a volatile switch. In one example, the selector is a volatile threshold switch. A selector may have a threshold voltage, Vₜₕ, that when a voltage V>Vₜₕ, the selector is in low resistance state. On the other hand, when V<Vₜₕ, the selector is in high resistance state. In one illustrative example, a voltage V was selected, V being above Vₜₕ while ½ V is below Vₜₕ. When +½ V is applied on one row (selected row), and −½V on one column (selected column), the device at the junction (selected device) has V so that it is in low resistance state. In this example, as a voltage divider the voltage drop on this selector becomes low, and main voltage V drops on the resistive memory element (e.g., ReRAM, such as memristor) for memristor set or reset. The remaining devices on selected row or column has either +½V or −½V (half selected devices), and they are in high resistance state. The remaining devices in the array are all unselected, all in high resistance state.

In one example, selectors are two-terminal devices or circuit elements that admit a non-linearly variable current dependent on the applied voltage applied across the terminals. Typically, the magnitude of the current is near zero at low voltages, and experiences a steep increase above a threshold voltage. The contrast in the sub-threshold and above-threshold voltages is referred to as the non-linearity, and this is a figure of merit for selector devices. In crossbar array examples of memristors, selectors integrated in series with each memristor switching device can be used to suppress off-state and half-select leakage currents, and these selectors may take the form of an oxide sandwiched between two metallic electrodes.

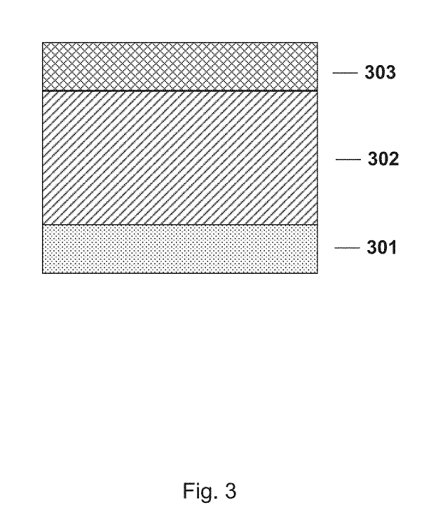

The selector may be a volatile switch. The selector may have any suitable configuration of components. FIG. 3 shows a schematic diagram of one example of a selector. For example, the selector may include a bottom electrode (301); a (switching) oxide layer (302) disposed over the bottom electrode, and a top electrode (303) disposed over the oxide layer. The oxide layer (302) may be disposed over a portion of a surface of the bottom electrode (301) or an entire surface of the bottom electrode (301). Similarly, the top electrode (303) may be disposed over a portion of a surface of the oxide layer or an entire surface of the oxide layer.

The bottom (301) and top (303) electrodes may include any electrically conductive material. For example, the electrically conductive material may be pure metal(s), metal alloy, metal oxide, metal nitride, etc. In one example, the material of the bottom and/or top electrodes may supply Cu ions (as a source) or absorb Cu ions (as a sink). Thus, the material of the bottom and/or top electrodes may have Cu solubility. In one example, the top electrode and the bottom electrode each includes at least one of Pt, Cu, Ru, Ti, Ta, and an alloy, an oxide, or a nitride thereof. The bottom and top electrodes may be symmetric—e.g., both electrodes share a common element, such as Cu. The term “element” herein may refer to the chemical symbol found on the Periodic Table. The bottom and top electrodes may be asymmetric—e.g., the electrodes do not share a common element. In one example, the bottom electrode may include Ta, Pt, or both. In one example, the top electrode may include Cu, Pt, or both. The material(s) of the electrodes may have any suitable thickness values. In one example, the top electrode includes a Ta layer having a thickness of about 2 nm and a Pt layer having a thickness of about 15 nm. In one example, the bottom electrode includes a Cu layer having a thickness of about 10 nm and a Pt layer having a thickness of about 20 nm.

The oxide of the switching oxide layer (302) may be any suitable metal oxide. For example, the oxide may be CuOₓ. CuOₓ herein may refer to both cuprous oxide (i.e., copper (I) oxide, or Cu₂O), and cupric oxide (i.e., copper (II) oxide, or CuO). Thus, the oxide may include either of or both of Cu₂O and CuO. In one example, the oxide of the selector includes cuprous oxide (Cu₂O). In one example, the oxide includes both Cu₂O and CuO. In one example, the oxide includes both Cu₂O and CuO, and the Cu₂O by weight is present at a higher amount than CuO. For example, the ratio CuO:Cu₂O by weight in the oxide layer is less than or equal to about 1:2—e.g., less than or equal to about 1:5, about 1:10, about 1:20, about 1:50, about 1:100, or smaller. The weight ratio of CuO and Cu₂O may be controlled and tailored to have any desired, predetermined value.

It is noted that there are three stable solid phases based on a Cu—O equilibrium phase diagram: Cu, Cu₂O, and CuO. Both Cu₂O and CuO show semiconductor behavior, with Cu₂O, a suboxide, surprisingly being more electrically resistive than CuO, a full or terminal oxide, according to resistivity data and band gap data: Cu₂O has a band gap of about 2.1 eV and resistivity of about 3×10² Ω-cm and CuO has a band gap of about 1.2-1.5 eV and a resistivity of about 10 Ω-cm.

The aforementioned weight ratio, with the Cu₂O present at much higher amount than CuO, may facilitate the condition that at the default state (i.e., no voltage applied at the selector), there is no Cu in the selector, or any Cu will react with CuO to form Cu₂O. In one example, the oxide layer is at least substantially free of elemental Cu (metal), such as completely free of elemental Cu. The relationship between Cu₂O and CuO may be elucidated further by thermodynamics. Specifically, for reaction

Cu₂O→Cu+CuO,

ΔH_{298,reaction}=+12.2 kJ; ΔS_{298,reaction}=15.9 J/K; and ΔG_{T,reaction}≈ΔG_{298,reaction}=12200−15.9 T>0 when T<767 K (494° C.). Accordingly, assuming (ΔG_{T,reaction}≈ΔG_{298,reaction} or ΔC_{p,reaction}=0), it was estimated from the Cu—O phase diagram that ΔG_{T,reaction}>0 up to 1060° C. It is noted that the assumption (ΔG_{T,reaction}≈ΔG_{298,reaction} or ΔC_{p,reaction}=0) may contain certain estimation error. In other words, at normal processing temperature, ΔG will drive the reaction in the direction:

Cu+CuO→Cu₂O.

In one example, a composition for the selector described herein may be selected within the (Cu₂O—CuO) two phase region, particularly near the Cu₂O line in the phase diagram, so that there is no Cu at the selector default state (i.e., when no external voltage is applied). The application of an external voltage will favor the reaction to go in the direction:

Cu₂O=Cu+CuO,

since both Cu and CuO are less resistive than Cu₂O, and Cu will drive the selector to the ON state or low resistance state. When the external voltage is removed (or below the holding voltage), ΔG will provide the driving force for the reaction (to return) in the direction:

Cu+CuO→Cu₂O,

consuming any existing Cu cation in the oxide matrix, and returning the selector to the high resistance state. It is noted that ΔG is a condition needed for the above reaction—thermodynamics determines the reaction direction, while kinetics determines the reaction rate. In this example, the selector described herein demonstrates a fast switching back to high resistance. In one example, the switching back voltage to high resistance state is about 0.5 V, but the value is not limited to 0.5 V.

The CuOₓ, with x being the oxygen to Cu atomic ratio, can be a mixture of Cu₂O and CuO. CuOₓ becomes Cu₂O with x=0.5, and becomes CuO with x=1.0. Therefore, the x in CuOₓ can vary from 0.5 to 1.0, and CuOₓ may be dispersed in an oxide matrix in the oxide layer. The oxide of the oxide matrix may be any suitable oxide. In one example, the matrix oxide is a dielectric oxide, such as a dielectric metal oxide. The selected dielectric oxide may behave like an insulator compared to CuOₓ, which may behave like a semiconductor. A dielectric oxide may be thermodynamically more stable than both Cu₂O and CuO. Dispersing CuOₓ in the dielectric oxide matrix may reduce the leakage current when the device is below threshold voltage, as well as reduce the operation current when the device is above threshold voltage. For example, the oxide matrix may include an oxide selected from SiO₂, Al₂O₃, Ta₂O₅, HfO₂, Y₂O₃, and ZrO₂. The matrix oxides are thermodynamically more stable than CuOₓ. In one example, a selector with CuOₓ embedded in an oxide matrix has an even lower leakage current than a selector with CuOₓ not embedded in an oxide matrix. Without being bound by any particular theory, it appears that the dielectric matrix oxide may limit the current to pass thorough only selected path in the matrix oxide, instead of passing through the whole oxide layer.

It is noted that unlike NbO₂, which may also be employed in a selector but undergo an insulator-metal transition at high temperature (about 800° C.), the CuOₓ in the selector described herein need not rely on undergoing such a transition, especially at such a high temperature.

The nonvolatile memory crossbar array described herein may be integrated into a system. For example, the system may include a processor and a nonvolatile memory crossbar array, such as any of those described herein.

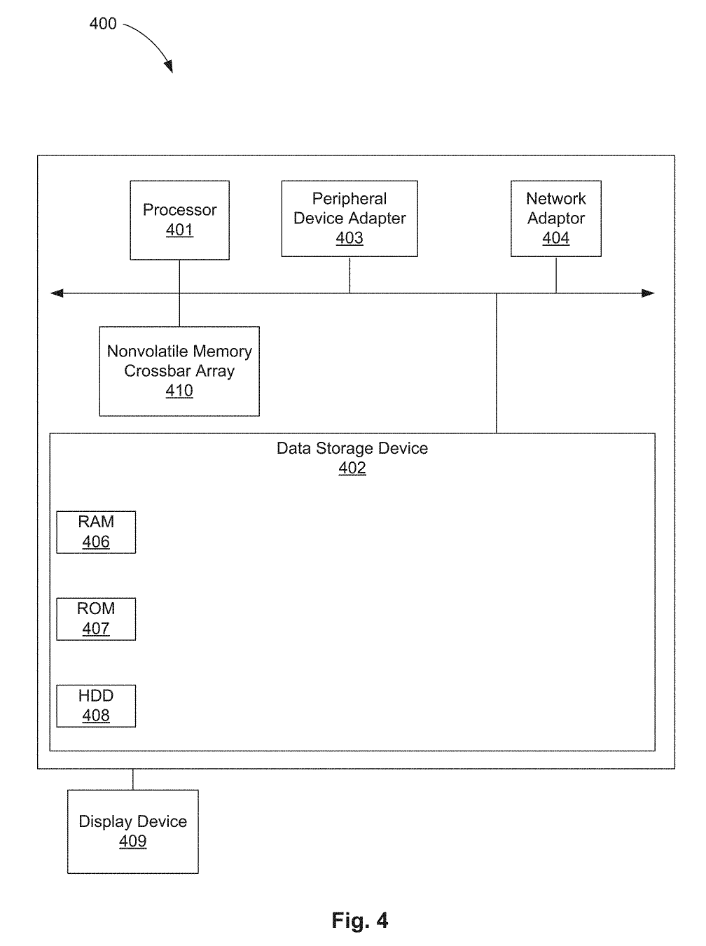

FIG. 4 provides a schematic diagram of a system (400) in one example. The system may be a computing system. The system (400) may be implemented in an electronic device. Examples of electronic devices include servers, desktop computers, laptop computers, personal digital assistants (PDAs), mobile devices, smartphones, gaming systems, and tablets, among other electronic devices.

The system (400) may be employed in any data processing scenario including, stand-alone hardware, mobile applications, etc., through a computing network. Further, the system (400) may be employed in a computing network, a public cloud network, a private cloud network, a hybrid cloud network, other forms of networks, or combinations thereof. In one example, the methods provided by the system (400) are provided as a service over a network by, for example, a third party. In this example, the service may include, for example, the following: a Software as a Service (“SaaS”) hosting a number of applications; a Platform as a Service (“PaaS”) hosting a computing platform including, for example, operating systems, hardware, and storage, among others; an Infrastructure as a Service (“IaaS”) hosting equipment such as, for example, servers, storage components, network, and components, among others; application program interface (“API”) as a service (“APIaaS”), other forms of network services, or combinations thereof. The present systems may be implemented on one or multiple hardware platforms, in which the modules in the system may be executed on one or across multiple platforms. Such modules may run on various forms of cloud technologies and hybrid cloud technologies or offered as a “SaaS” (Software as a service) that may be implemented on or off the cloud. In another example, the methods provided by the system (400) are executed by a local administrator.

To achieve its desired operation, the system (400) may include various hardware components. Examples of these hardware components may include a number of processors (401), a number of data storage devices (402), a number of peripheral device adapters (403), and a number of network adapters (404). These hardware components may be interconnected through the use of a number of busses and/or network connections. In one example, any combination of the processor (401), data storage device (402), peripheral device adapters (403), the nonvolatile memory crossbar array (410) described herein, and a network adapter (404) may be communicatively coupled using a bus (405).

The data storage device (402) may store data such as machine-readable instructions (e.g., computer code) that may be executed by the processor (401) or other processing device. For example, the data storage device (402) may specifically store machine-readable instructions for a number of applications that the processor (401) may execute to implement at least the operation described herein.

The data storage device (402) may include various types of memory modules, including volatile and nonvolatile memories. For example, the data storage device (402) may include Random Access Memory (“RAM”) (406), Read Only Memory (“ROM”) (407), and Hard Disk Drive (“HDD”) memory (408). Other suitable types of memory may also be employed. In one example, different types of memory in the data storage device (402) are used for different data storage needs. For example, the processor (401) may boot from Read Only Memory (“ROM”) (407), maintain nonvolatile storage in the Hard Disk Drive (“HDD”) memory (408), and execute machine-readable instructions stored in Random Access Memory (“RAM”) (406).

The data storage device (402) may include a machine-readable medium, such as a computer readable storage medium, a non-transitory computer readable medium, etc. For example, the data storage device (402) may be an electronic, magnetic, optical, electromagnetic, infrared, or semiconductor system, apparatus, or device, or any suitable combination of the foregoing. Some examples of the computer readable storage medium include the following: an electrical connection having a number of wires, a portable computer diskette, a hard disk, a random access memory (RAM), a read-only memory (“ROM”), an erasable programmable read-only memory (“EPROM” or Flash memory), a portable compact disc read-only memory (“CD-ROM”), an optical storage device, a magnetic storage device, or any suitable combination thereof. A computer readable storage medium herein may refer to any non-transitory, tangible medium that may contain, or store, machine-readable instructions (e.g., computer usable program code) for use by or in connection with an instruction execution system, apparatus, or device.

The hardware adapters, including a peripheral device adapter (403) and a network adaptor (404), in the system (400) may facilitate the processor (401) to interface with various other hardware elements, external and internal to the system (400). For example, the peripheral device adapter (403) may provide an interface to input/output devices, such as, for example, display device (409), a mouse, or a keyboard. The peripheral device adapter (403) may also provide access to other external devices, such as an external storage device, a number of network devices such as, for example, servers, switches, and routers, client devices, other types of computing devices, and combinations thereof.

The display device (409) may be provided to allow a user of the system (400) to interact with and implement the operation of the system (400). The peripheral device adapter (403) may also create an interface between the processor (401) and the display device (409), a printer, or other media output devices. The network adapter (404) may provide an interface to other computing devices within, for example, a network, thereby facilitating the transmission of data between the system (400) and other devices located within the network.

The system (400) may, when executed by the processor (401), display the number of graphical user interfaces (“GUIs”) on the display device (409) associated with the executable machine-readable instructions (e.g., program code) representing the number of applications stored on the data storage device (402). The GUIs may display, for example, interactive screenshots that allow a user to interact with the system (400) to input values in association with a nonvolatile memory crossbar array (410), as described herein. Additionally, via making a number of interactive gestures on the GUIs of the display device (409), a user may obtain a value from certain calculations based on the input data. Examples of display devices (409) include a computer screen, a laptop screen, a mobile device screen, a personal digital assistant (“PDA”) screen, and a tablet screen, among other display devices.

The system (400) may include a number of modules employed in the implementation of the systems and methods described herein. The various modules within the system (400) include machine-readable instructions, such as an executable program code, that may be executed separately. The various modules may be stored as separate computer program products. The various modules within the system (400) may also be combined within a number of computer program products; each computer program product including a number of the modules.

Method of Manufacturing

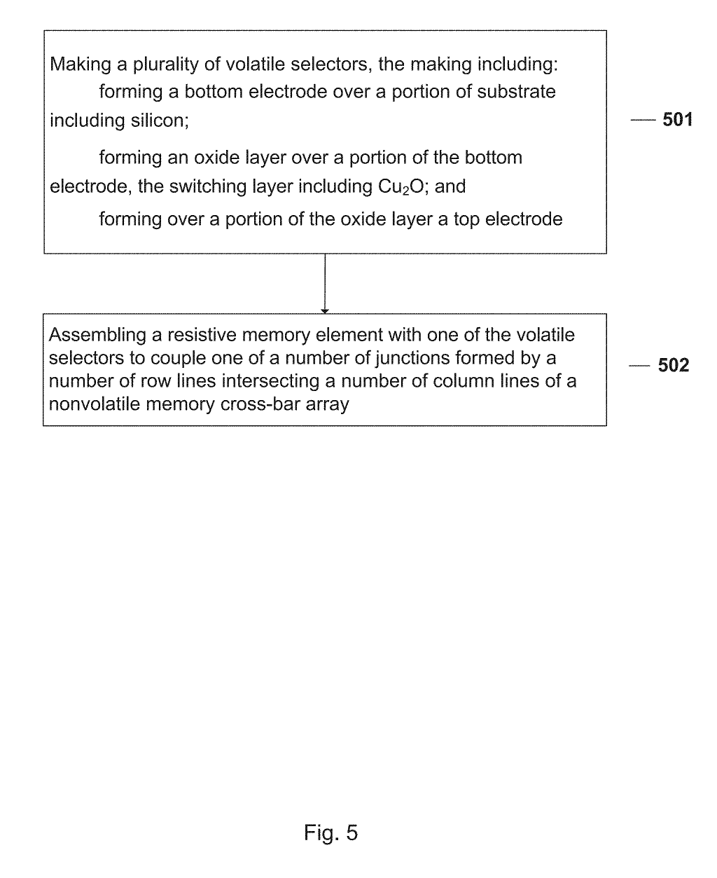

The nonvolatile memory crossbar array described herein may be manufactured by a method involving any suitable number of processes. FIG. 5 is a flow chart showing an example of such a method. As shown in FIG. 5, the method of manufacturing may include first making a plurality of volatile selectors (501). The process of making each selector may further include forming a bottom electrode from a portion of substrate including silicon. The substrate may, for example, be a Si wafer with an oxide layer (e.g., silica) formed over the substrate by thermal oxidation. In one example, the topographical oxide layer is about 200 nm. Additionally, the bottom electrode may be formed by any suitable technique, including, for example, e-beam evaporation, such as through a shadow mask. The bottom electrode may be any of those described herein.

The process of making may further include forming a (switching) oxide layer over a portion of the first electrode, the switching layer including Cu₂O. The (switching) oxide layer may be formed by any suitable technique, including, for example, sputtering. One example of sputtering is reactive sputtering. The reactive sputtering may involve any suitable sputtering target, such as one including a material selected from Cu, CuO₂, and CuO. The sputtering may be conducted in oxygen or inert gas.

The process of making may further include forming over a portion of the oxide layer a top electrode. The top electrode may be formed by any suitable technique, including, for example, e-beam evaporation, such as through a shadow mask. The top electrode may be any of those described herein.

As shown in FIG. 5, The method of manufacturing may further include assembling a resistive memory element with one of the volatile selectors to couple one of a number of junctions formed by a number of row lines intersecting a number of column lines of a nonvolatile memory crossbar array (502). The term “couple” herein may refer to electrical coupling.

The method of manufacturing described herein may include additional processes. For example, in the case where the CuOₓ is embedded in a matrix oxide (e.g., dielectric oxide), the CuOₓ and the matrix oxide are co-deposited. In one example wherein the matrix oxide is SiO₂, the CuOₓ, and SiO₂ are co-deposited. In this example, the “x” in CuOₓ is slighter higher than 0.5 to prevent Cu ions from being present in the matrix oxide.

At least as a result of the aforedescribed features, the array described herein may have a number of advantages, including: large non-linearity, low energy (not joule heating based), and high current density. Also, the array described herein, particularly due to the selector described herein, may exhibit reduced sneak path current, as well as volatile switching that may return to high resistance state before voltage decrease to zero.

### NON-LIMITING WORKING EXAMPLES

One Experiment was conducted to observe volatile threshold switching behaviors as deduced from reaction thermodynamics. Specifically, a crossbar dog bone selector sample in micrometer size was fabricated. The bottom electrode (BE) of the sample included Ta 2 nm/Pt 15 nm. The switching oxide of the sample included CuOx as a product of reactive sputtering form Cu target. The top electrode (BE) of the sample included Cu 10 nm/Pt 20 nm.

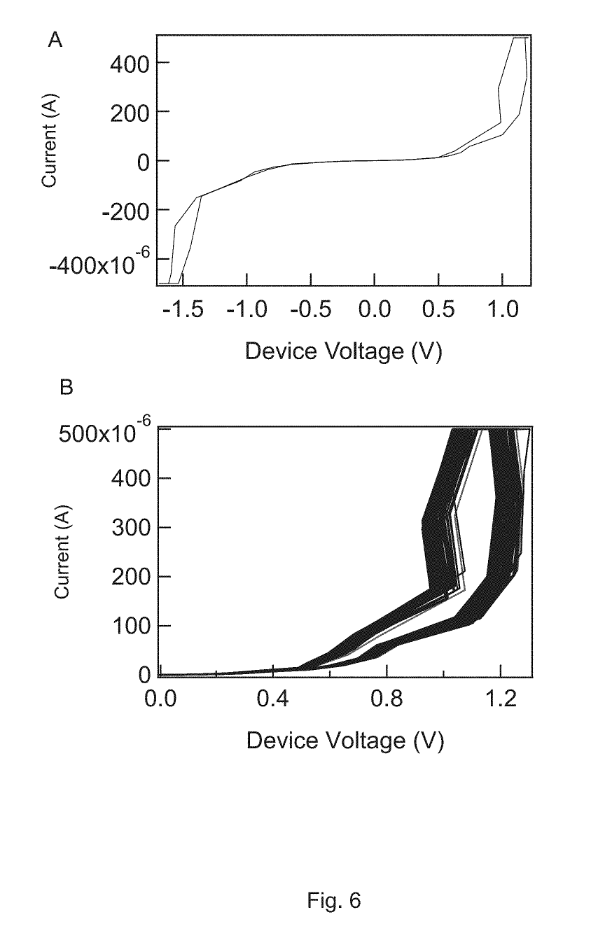

Volatile threshold switching of the sample was observed using Agilent 4156C semiconductor parameter analyzer. During a two-probe/wire measurement (one-probe on TE and the other on BE), it was observed that the sample showed volatile threshold switching in both voltage polarities (FIG. 6A). The samples also showed repeatable volatile threshold switching in 100 cycles under positive voltage polarity (FIG. 6B). Switching under one voltage polarity repeatedly is an effective way to distinguish the switching being volatile or non-volatile in nature. Additionally, it was observed that that the sample device returned to high resistance state before voltage decreased to zero. It was also concluded that the device sample in this Experiment achieved negative differential resistance (“NDR”), similar to that observed in VO₂ and NbO₂, without an insulator-metal transition.

Additional Notes

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

While the present teachings have been described in conjunction with various examples, it is not intended that the present teachings be limited to such examples. The above-described examples may be implemented in any of numerous ways. For example, some examples may be implemented using hardware, software or a combination thereof. When any aspect of an example is implemented at least in part in software, the software code may be executed on any suitable processor or collection of processors, whether provided in a single computer or distributed among multiple computers.

Various examples described herein may be embodied at least in part as a non-transitory machine-readable storage medium (or multiple machine-readable storage media)—e.g., a computer memory, a floppy disc, compact disc, optical disc, magnetic tape, flash memory, circuit configuration in Field Programmable Gate Arrays or another semiconductor device, or another tangible computer storage medium or non-transitory medium) encoded with at least one machine-readable instructions that, when executed on at least one machine (e.g., a computer or another type of processor), cause at least one machine to perform methods that implement the various examples of the technology discussed herein. The computer readable medium or media may be transportable, such that the program or programs stored thereon may be loaded onto at least one computer or other processor to implement the various examples described herein.

The term “machine-readable instruction” is employed herein in a generic sense to refer to any type of machine code or set of machine-executable instructions that may be employed to cause a machine (e.g., a computer or another type of processor) to implement the various examples described herein. The machine-readable instructions may include, but are not limited to, a software or a program. The machine may refer to a computer or another type of processor specifically designed to perform the described function(s). Additionally, when executed to perform the methods described herein, the machine-readable instructions need not reside on a single machine, but may be distributed in a modular fashion amongst a number of different machines to implement the various examples described herein.

Machine-executable instructions may be in many forms, such as program modules, executed by at least one machine (e.g., a computer or another type of processor). Generally, program modules include routines, programs, objects, components, data structures, etc. that perform particular tasks or implement particular abstract data types. Typically, the operation of the program modules may be combined or distributed as desired in various examples.

Also, the technology described herein may be embodied as a method, of which at least one example has been provided. The acts performed as part of the method may be ordered in any suitable way. Accordingly, examples may be constructed in which acts are performed in an order different than illustrated, which may include performing some acts simultaneously, even though shown as sequential acts in illustrative examples.

The indefinite articles “a” and “an,” as used herein in this disclosure, including the claims, unless clearly indicated to the contrary, should be understood to mean “at least one.” Any ranges cited herein are inclusive.

The terms “substantially” and “about” used throughout this disclosure, including the claims, are used to describe and account for small fluctuations, such as due to variations in processing. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The phrase “and/or,” as used herein in this disclosure, including the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “including” may refer, in one example, to A only (optionally including elements other than B); in another example, to B only (optionally including elements other than A); in yet another example, to both A and B (optionally including other elements); etc.

As used in this disclosure, including the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of,” “Consisting essentially of,” when used in the claims, shall have its ordinary meaning as used in the field of patent law.

In this disclosure, including the claims, all transitional phrases such as “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, §2111.03.

What is claimed:

1. A nonvolatile memory crossbar array, including:
a number of junctions formed by a number of row lines intersecting a number of column lines; and
a resistive memory element in series with a selector at each of the junctions coupling between one of the row lines and one of the column lines, the selector being a volatile switch including:
a bottom electrode;
an oxide layer disposed over the bottom electrode, the oxide layer including Cu₂O; and
a top electrode disposed over the oxide layer.

2. The nonvolatile memory crossbar array of claim 1, wherein the resistive memory element is a resistive random-access memory.

3. The nonvolatile memory crossbar array of claim 1, wherein the resistive memory element is a memristor.

4. The nonvolatile memory crossbar array of claim 1, wherein the oxide layer further includes CuO, and a ratio by weight of CuO:Cu₂O is less than or equal to 1:2.

5. The nonvolatile memory crossbar array of claim 1, wherein the selector is at least substantially free of elemental Cu.

6. The nonvolatile memory crossbar array of claim 1, wherein the Cu₂O in the oxide layer is dispersed in an oxide matrix, the oxide matrix including an oxide selected from SiO₂, Al₂O₃, Ta₂O₅, HfO₂, Y₂O₃, and ZrO₂,

7. The nonvolatile memory crossbar array of claim 1, wherein the top electrode and the bottom electrode includes at least one of Pt, Cu, Ru, Ti, Ta, and an alloy, an oxide, or a nitride thereof.

8. The nonvolatile memory crossbar array of claim 1, wherein the top electrode and the second electrode are symmetric.

9. The nonvolatile memory crossbar array of claim 1, wherein the top electrode and the second electrode are asymmetric.

10. A system, including:
a processor; and
a nonvolatile memory crossbar array coupled to the processor, the memristor crossbar array including:
a number of junctions formed by a number of row lines intersecting a number of column lines;
a resistive memory element in series with a selector at each of the junctions coupling between one of the row lines and one of the column lines, the selector being a volatile switch including:
a bottom electrode;
an oxide layer disposed over the bottom electrode, the oxide layer including Cu₂O; and
a top electrode disposed over the oxide layer; and
a current collection line to collect all currents output from the resistive memory element and the selector at the junctions through their respective column lines.

11. The system of claim 10, wherein the oxide layer further includes CuO, and a ratio by weight of CuO:Cu₂O is less than or equal to 1:2.

12. The system of claim 10, wherein the CuO in the oxide layer is dispersed in an oxide matrix, the oxide matrix including an electric oxide selected from SiO₂, Al₂O₃, Ta₂O₅, HfO₂, Y₂O₃, and ZrO₂.

13. The system of claim 10, wherein the resistive memory element is a memristor.

14. A method of manufacturing, including:
making a plurality of volatile selectors, the making including:
forming a bottom electrode over a portion of substrate including silicon;
forming an oxide layer over a portion of the bottom electrode, the oxide layer including Cu₂O; and
forming over a portion of the oxide layer a top electrode; and
assembling a resistive memory element with one of the volatile selectors to couple one of a number of junctions formed by a number of row lines intersecting a number of column lines of a nonvolatile memory crossbar array.

15. The method of manufacturing of claim 14, wherein the forming a switching layer includes sputtering from a target including a material selected from Cu, CuO₂, and CuO.
